(19) United States
(12) Patent Application Publication
(10) Pub. No.: US 2025/0132202 A1
(43) Pub. Date: Apr. 24, 2025

(54) SEMICONDUCTOR PACKAGE AND MANUFACTURING METHOD THEREOF

(71) Applicant: SAMSUNG ELECTRONICS CO., LTD., Suwon-si (KR)

(72) Inventors: Seokkyu Lee, Suwon-si (KR); Wonbin Shin, Suwon-si (KR); Kiseok Kim, Suwon-si (KR); Jihye Shim, Suwon-si (KR); Jeonggi Jin, Suwon-si (KR)

(21) Appl. No.: 18/816,416

(22) Filed: Aug. 27, 2024

(30) Foreign Application Priority Data
Oct. 20, 2023 (KR) 10-2023-0141407

(51) Int. Cl. H01L 21/768

(52) U.S. Cl. CPC H01L 21/76879; H01L 21/76871

(57) ABSTRACT

A method of manufacturing a semiconductor package with a semiconductor chip including an active surface and an inactive surface opposite to the active surface is presented. The method includes attaching, to the active surface, a film structure including an insulating layer and a first seed layer contacting the insulating layer. A via hole is formed by penetrating the insulating layer and the first seed layer followed by a descumming the insulating layer and the first seed layer in which the via hole is formed. A second seed layer is formed on the insulating layer and on the first seed layer on which the descum process was performed. A photoresist pattern on the second seed layer enables forming a conductive via by filling both a space defined by the via hole with a conductive material and by filling a space defined by the photoresist pattern with the conductive material.

### CROSS-REFERENCE TO RELATED APPLICATION

This application is based on and claims priority under 35 U.S.C. §119 to Korean Patent Application No. 10-2023-0141407, filed on Oct. 20, 2023, in the Korean Intellectual Property Office, the disclosure of which is incorporated by reference herein in its entirety.

### BACKGROUND

With the rapid development in the electronics industry and demands for users, electronic devices are becoming increasingly compact and lightweight. Because of the downsizing and weight reduction of electronic devices, semiconductor packages used therein are also decreasing in size and weight. In addition, there is a growing demand for high reliability in semiconductor packages, along with requirements for high performance and capacity. As the semiconductor packages become highly powered and have increased capacity, the power consumption of the semiconductor packages also increases. As a result, the importance of the structure of a redistribution structure, which adapts to the size and performance of semiconductor packages and stably supplies power thereto, is increasing.

### SUMMARY

The inventive concept relates to a semiconductor package having improved reliability and a method of manufacturing the same.

A method is provided of manufacturing a semiconductor package that includes a semiconductor chip including an active surface and an inactive surface opposite to the active surface, the method including attaching, to the active surface, a film structure including an insulating layer and a first seed layer contacting the insulating layer, forming a via hole penetrating the insulating layer and the first seed layer, performing a descum process on the insulating layer and the first seed layer in which the via hole is formed, forming a second seed layer on the insulating layer and the first seed layer on which the descum process was performed, forming a photoresist pattern on the second seed layer, and forming a conductive via by filling a space defined by the via hole with a conductive material and forming a conductive pattern by filling a space defined by the photoresist pattern with the conductive material.

A method of manufacturing a semiconductor package is provided that includes a semiconductor chip including an active surface and an inactive surface opposite to the active surface, the method including attaching, to the active surface, a film structure including an insulating layer, a first seed layer, a release layer, and a carrier film which are sequentially stacked, forming a first photoresist pattern on the first seed layer after the release layer and the carrier film are removed, removing the first photoresist pattern after etching a portion of the first seed layer that does not overlap the first photoresist pattern, forming a via hole by removing a portion of the insulating layer that does not overlap the first seed layer, performing a descum process on the first seed layer and the insulating layer in which the via hole is formed, forming a second seed layer on the first seed layer and the insulating layer on which the descum process was performed, forming a second photoresist pattern on the second seed layer, and forming a conductive via by filling a space defined by the via hole with a conductive material and forming a conductive pattern by filling a space defined by the second photoresist pattern with the conductive material.

A method is provided of manufacturing a semiconductor package that includes a semiconductor chip including an active surface and an inactive surface opposite to the active surface and an intermediate connection structure having a multilayered structure and surrounding the semiconductor chip, the method including attaching, to the active surface, a film structure including a photosensitive insulating layer, a first seed layer, a release layer, and a carrier film which are sequentially stacked, forming a first photoresist pattern on the first seed layer after the release layer and the carrier film are removed, removing the first photoresist pattern after etching a portion of the first seed layer that does not overlap the first photoresist pattern, forming a via hole by removing a portion of the photosensitive insulating layer that does not overlap the first seed layer, performing a descum process on the first seed layer and the photosensitive insulating layer in which the via hole is formed, forming a second seed layer on the first seed layer and the photosensitive insulating layer on which the descum process was performed, forming a second photoresist pattern on the second seed layer, and forming a conductive via by filling a space defined by the via hole with a conductive material and forming a conductive pattern by filling a space defined by the second photoresist pattern with the conductive material.

### BRIEF DESCRIPTION OF THE DRAWINGS

Implementations will be more clearly understood from the following detailed description taken in conjunction with the accompanying drawings in which:

FIG. 1 is a cross-sectional view of an example semiconductor package;

FIG. 2 is an enlarged view showing an enlarged region A of FIG. 1;

FIG. 3 is a cross-sectional view of an example semiconductor package;

FIG. 4 is an enlarged view showing an enlarged region B of FIG. 3;

FIG. 5 is a flowchart of an example method of manufacturing a semiconductor package; and

FIGS. 6 to 14 are cross-sectional views sequentially showing an example method of manufacturing a semiconductor package.

### DETAILED DESCRIPTION OF THE EMBODIMENTS

Hereinafter, embodiments are described in detail with reference to the attached drawings. However, the implementation should not be limited to the embodiments described below and may be realized in many different forms. The embodiments below are not provided to be complete, but rather provided to fully convey the scope to one of ordinary skill in the art.

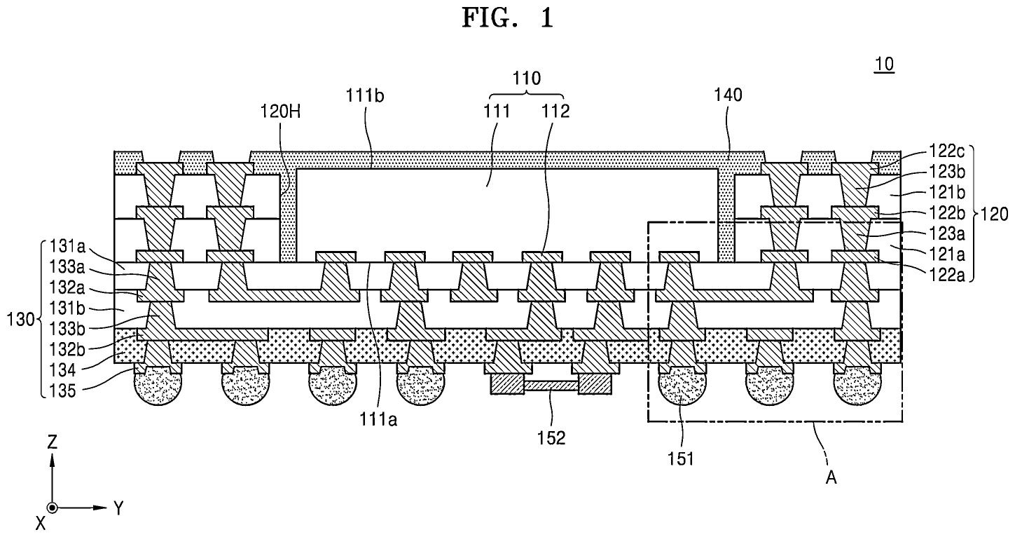

FIG. 1 is a cross-sectional view of a semiconductor package. Specifically, a semiconductor package 10 of FIG. 1 may be a semiconductor package manufactured in a chip-first manner.

In the present specification, a lower connection structure 130 and an intermediate connection structure 120 described below with reference to FIG. 1 may be simply referred to as connection structures. Also, lower insulating layers 131a and 131b and intermediate insulating layers 121a and 121b may be simply referred to as insulating layers. In addition, lower conductive pattern layers 132a and 132b and intermediate conductive pattern layers 122a, 122b, and 122c described below with reference to FIG. 1 may be simply referred to as conductive pattern layers. Furthermore, lower vias 133a and 133b and intermediate vias 123a and 123b described below with reference to FIG. 1 may be simply referred to as vias.

Referring to FIG. 1, the semiconductor package 10 may include the lower connection structure 130, a semiconductor chip 110 arranged on an upper surface of the lower connection structure 130, the intermediate connection structure 120 arranged on the upper surface of the lower connection structure 130, and a molding layer 140 covering an upper surface of the semiconductor chip 110. In some implementations, the semiconductor package 10 may further include an external connection terminal 151 arranged on a lower surface of the lower connection structure 130. In some implementations, the semiconductor package 10 may further include a capacitor 152 arranged on the lower surface of the lower connection structure 130.

The lower connection structure 130 may have substantially a planar shape or a panel shape. The lower connection structure 130 may include the upper surface and the lower surface that are opposite to each other, and the upper surface and the lower surface may each be flat. Hereinafter, each of a first horizontal direction (an X direction) and a second horizontal direction (a Y direction) perpendicular to the first horizontal direction (the X direction) may be defined as a direction parallel to the upper surface of the lower connection structure 130, and a vertical direction (a Z direction) may be defined as a direction perpendicular to the upper surface of the lower connection structure 130. The lower connection structure 130 may be, for example, a printed circuit board (PCB).

The lower connection structure 130 may connect between the semiconductor chip 110 and the external connection terminal 151, between the intermediate connection structure 120 and the semiconductor chip 110, and between the intermediate connection structure 120 and the external connection terminal 151. The lower connection structure 130 may include lower insulating layers 131a and 131b, lower conductive pattern layers 132a and 132b on the lower insulating layers 131a and 131b, and lower vias 133a and 133b that penetrate the lower insulating layers 131a and 131b to contact the lower conductive pattern layers 132a and 132b. At least one lower conductive pattern layer 132a and 132b and at least one lower via 133a and 133b may provide an electrical path connecting between the semiconductor chip 110 and the external connection terminal 151, an electrical path connecting between the intermediate connection structure 120 and the semiconductor chip 110, and an electrical path connecting between the intermediate connection structure 120 and the external connection terminal 151. In some implementations, the lower connection structure 130 may further include a lower protective layer 134 and a lower pad 135 on the lower protective layer 134. The lower connection structure 130 may be a redistribution structure or a PCB.

The lower insulating layers 131a and 131b may include a first lower insulating layer 131a and a second lower insulating layer 131b. The lower conductive pattern layers 132a and 132b may include a first lower conductive pattern layer 132a and a second lower conductive pattern layer 132b. The lower vias 133a and 133b may include a first lower via 133a and a second lower via 133b. For example, the lower connection structure 130 may include a first lower insulating layer 131a on a lower surface of the semiconductor chip 110 and a lower surface of the intermediate connection structure 120, a first lower conductive pattern layer 132a on a lower surface of the first lower insulating layer 131a, a first lower via 133a penetrating the first lower insulating layer 131a and contacting the first lower conductive pattern layer 132a, a second lower insulating layer 131b on the lower surface of the first lower insulating layer 131a and a lower surface of the first lower conductive pattern layer 132a, a second lower insulating layer 131b on the lower surface of the first lower insulating layer 131a and the lower surface of the first lower conductive pattern layer 132a, the second lower conductive pattern layer 132b on the lower surface of the second lower insulating layer 131b, and a second lower via 133b penetrating the second lower insulating layer 131b and extending between the first lower conductive pattern layer 132a and the second lower conductive pattern layer 132b. Unlike the illustration of FIG. 1, however, the lower connection structure 130 may include more or fewer lower conductive pattern layers than two lower conductive pattern layers. The first lower conductive pattern layer 132a may be connected to a first intermediate conductive pattern layer 122a of the intermediate connection structure 120 and a chip pad 122 of the semiconductor chip 110 through the first lower vias 133a, and the second lower conductive pattern layer 132b may be connected to the first lower conductive pattern layer 132a through the second lower via 133b.

The lower insulating layers 131a and 131b may include, for example, inorganic insulating materials, organic insulating materials, or a combination thereof. The inorganic insulating material may include, for example, silicon oxide, silicon nitride, or a combination thereof. The organic insulating material may include, for example, polyimide, epoxy resin, or a combination thereof. The lower conductive pattern layers 132a and 132b and the lower vias 133a and 133b may include, for example, conductive materials including copper (Cu), gold (Au), silver (Ag), nickel (Ni), tungsten (W), aluminum (Al), or a combination thereof. In some implementations, the lower conductive pattern layers 132a and 132b and the lower vias 133a and 133b may further include barrier materials that keep the aforementioned conductive materials from diffusing outside the lower conductive pattern layers 132a and 132b and the lower vias 133a and 133b. The barrier material may include, for example, titanium (Ti), tantalum (Ta), titanium nitride (TiN), tantalum nitride (TaN), or a combination thereof.

The lower protective layer 134 may be located on the lower surface of the second lower insulating layer 131b. The lower protective layer 134 may physically and/or chemically protect the lower connection structure 130 from the surrounding environment. In some implementations, the lower protective layer 134 may include a composite material. That is, the lower protective layer 134 may include a matrix and a filler material in the matrix. The matrix may include a polymer, and the filler material may include silica, titania, or a combination thereof.

The lower pad 135 may be located on the lower surface of the lower protective layer 134 and contact the second lower conductive pattern layer 132b by penetrating the lower protective layer 134, thus connecting between the second lower conductive pattern layer 132b and the external connection terminal 151. The lower pad 135 may include, for example, a conductive material including Cu, Au, Ag, Ni, W, Al, or a combination thereof. In some implementations, the lower pad 135 may further include a barrier material to prevent the conductive material from diffusing outside the lower pad 135. The barrier material may include, for example, Ti, Ta, TiN, TaN, or a combination thereof. In some implementations, the lower pad 135 may further include a wetting material to improve wettability with the conductive material and the external connection terminal 151. When the conductive material includes Cu, the wetting material may include Ni, Au, or a combination thereof. In an implementation, the lower pad 135 may be under bump metallurgy (UBM).

The semiconductor chip 110 may include a body 111 and a chip pad 112 on a lower surface of the body 111. The body 111 may include a substrate and an integrated circuit on the substrate. A surface of the semiconductor chip 110 on which the integrated circuit is formed may be referred to as an active surface 111a, while a surface of the semiconductor chip 110 opposite to the active surface 111a may be referred to as an inactive surface 111b. Referring to FIG. 1, the active surface 111a of the semiconductor chip 110 may be the lower surface of the semiconductor chip 110, and the inactive surface 111b of the semiconductor chip 110 may be the upper surface of the semiconductor chip 110.

The substrate may include a semiconductor material, for example, a group IV semiconductor material, a group III-V semiconductor material, a group II-VI semiconductor material, or a combination thereof. The group IV semiconductor material may include, for example, silicon (Si), germanium (Ge), or a combination thereof. The group III-V semiconductor material may include, for example, gallium arsenide (GaAs), indium phosphide (InP), gallium phosphide (GaP), indium arsenide (InAs), indium antimonide (InSb), indium gallium arsenide (InGaAs), or a combination thereof. The group II-VI semiconductor material may include, for example, zinc telluride (ZnTe), cadmium sulfide (Cds), or a combination thereof. The integrated circuit may be an arbitrary integrated circuit including a memory circuit, a logic circuit, or a combination thereof. The memory circuit may include, for example, a dynamic random access memory (DRAM) circuit, a static random access memory (SRAM) circuit, a flash memory circuit, an electrically erasable and programmable read-only memory (EEPROM) circuit, a phase-change random access memory (PRAM) circuit, a magnetic random access memory (MRAM) circuit, a resistive random access memory (RRAM) circuit, or a combination thereof. The logic circuit may include, for example, a central processing unit (CPU) circuit, a graphics processing unit (GPU) circuit, a controller circuit, an application specific integrated circuit (ASIC) circuit, an application processor (AP) circuit, or a combination thereof.

The chip pad 112 may be located on the lower surface of the semiconductor chip 110. The chip pad 112 may connect the integrated circuit of the body 111 to the lower connection structure 130. The chip pad 112 may include, for example, a conductive material including Cu, Au, Ag, Ni, W, Al, or a combination thereof.

The intermediate connection structure 120 may be located on the lower connection structure 130 and may be configured to connect the lower connection structure 130 and an upper connection structure (not shown) that may be located on the semiconductor chip 110. The intermediate connection structure 120 may be located around the semiconductor chip 110. In some implementations, the intermediate connection structure 120 may include a hole 120H, and the semiconductor chip 110 may be located in the hole 120H of the intermediate connection structure 120. That is, the intermediate connection structure 120 may surround the semiconductor chip 110.

The intermediate connection structure 120 may include at least one intermediate via 123a and 123b configured to connect between the lower connection structure 130 and the upper connection structure (not shown). In some implementations, the intermediate connection structure 120 may further include at least one intermediate insulating layer 121a and 121b through which at least one intermediate via 123a and 123b passes. In some implementations, the intermediate connection structure 120 may further include a plurality of intermediate conductive pattern layers 122a, 122b, and 122c that are located on at least one intermediate insulating layer 121a and 121b and connected to each other by at least one intermediate via 123a and 123b. The intermediate vias 123a and 123b and the intermediate conductive pattern layers 122a to 122c may provide an electrical path configured to connect between the lower connection structure 130 and the upper connection structure (not shown).

For example, the intermediate connection structure 120 may include the first intermediate insulating layer 121a on the upper surface of the lower connection structure 130, the first intermediate conductive pattern layer 122a arranged on the upper surface of the first lower insulating layer 131a, a second intermediate conductive pattern layer 122b arranged on the upper surface of the first intermediate insulating layer 121a, a first intermediate via 123a penetrating the first intermediate insulating layer 121a and contacting the first intermediate conductive pattern layer 122a, the second intermediate insulating layer 121b arranged on the upper surface of the first intermediate insulating layer 121a, the third intermediate conductive pattern layer 122c arranged on the upper surface of the second intermediate insulating layer 121b, and the second intermediate via 123b penetrating the second intermediate insulating layer 121b and contacting the second intermediate conductive pattern layer 122b.

Unlike the illustration of FIG. 1, however, the intermediate connection structure 120 may include more or fewer lower conductive pattern layers than three lower conductive pattern layers. The second intermediate via 123b may connect between the third intermediate conductive pattern layer 122c and the second intermediate conductive pattern layer 122b, and the first intermediate via 123a may connect between the second intermediate conductive pattern layer 122b and the first intermediate conductive pattern layer 122a.

The intermediate insulating layers 121a and 121b may include insulating materials. Examples of the insulating material may include thermosetting resin such as epoxy resin, thermoplastic resin such as polyimide, or an insulating material, for example, prepreg, Ajinomoto Build-up Film (ABF), FR-4, bismaleimide triazine (BT), in which the core of an inorganic filler material and/or glass fiber, glass cloth, glass fabric, or the like is impregnated with the above resin. The intermediate conductive pattern layers 122a to 122c and the intermediate vias 123a and 123b may include, for example, conductive materials including Cu, Au, Ag, Ni, W, Al, or a combination thereof. In some implementations, the intermediate conductive pattern layers 122a to 122c and the intermediate vias 123a and 123b may further include barrier materials that keep the aforementioned conductive materials from diffusing outside the intermediate conductive pattern layers 122a to 122c and the intermediate vias 123a and 123b. The barrier material may include, for example, Ti, Ta, TiN, TaN, or a combination thereof.

The molding layer 140 may expose the intermediate connection structure 120 while covering the upper surface of the semiconductor chip 110. The molding layer 140 may fill a space between the semiconductor chip 110 and the upper connection structure (not shown). In some implementations, the molding layer 140 may further fill a space between the intermediate connection structure 120 and the semiconductor chip 110. In some implementations, the molding layer 140 may further fill at least a portion of a space between the lower connection structure 130 and the semiconductor chip 110.

The molding layer 140 may include, for example, thermosetting resin such as epoxy resin or thermoplastic resin such as polyimide. In addition, a molding material such as an epoxy mold compound (EMC) or a photosensitive material such as a photoimageable encapsulant (PIE) may be used for the molding layer 140. In some implementations, the molding layer 140 may include a composite material including a matrix and a filler material in the matrix. The matrix may include a polymer, and the filler material may include silica, titania, or a combination thereof.

The external connection terminal 151 may be located on the lower surface of the lower pad 135 of the lower connection structure 130. The external connection terminal 151 may include, for example, a conductive material including tin (Sn), lead (Pb), Ag, Cu, or a combination thereof. The external connection terminal 151 may be formed by using, for example, solder balls. The external connection terminal 151 may connect the semiconductor package 100 to a circuit board, another semiconductor package, an interposer, or a combination thereof. The capacitor 152 may stabilize the power. The capacitor 152 may be connected to the lower connection structure 130 through the lower pad 135 of the lower connection structure 130.

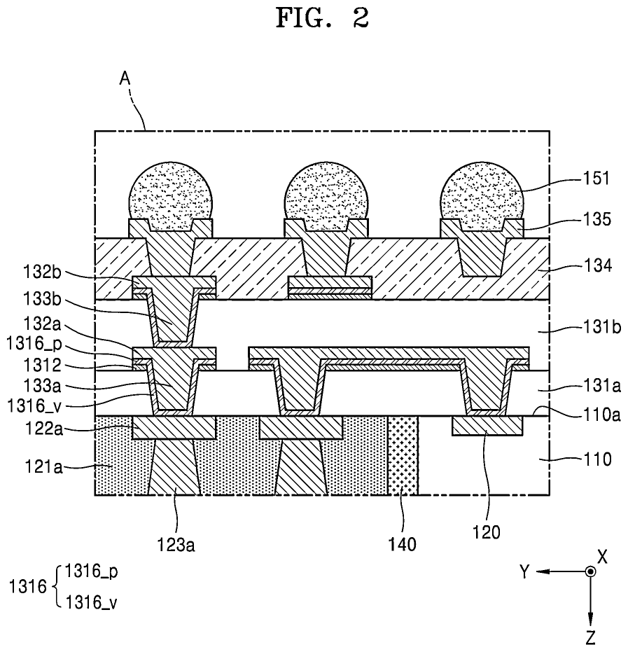

FIG. 2 is an enlarged view showing an enlarged region A of FIG. 1, rotated one half turn around the X-axis.

Referring to FIG. 2, the lower connection structure (130, see FIG. 1) may further include a first seed layer 1312 and a second seed layer 1316. The first seed layer 1312 may be between the first lower conductive pattern layer 132a and the first lower insulating layer 131a. The second seed layer 1316 may include a first area 1316_v between the first lower via 133a and the first lower insulating layer 131a and a second area 1316_p between the first seed layer 1312 and the first lower conductive pattern layer 132a.

The first seed layer 1312 may extend along a surface of the first lower conductive pattern layer 132a. In this case, an upper surface of the first seed layer 1312 may be parallel to the upper surface of the first lower conductive pattern layer 132a.

A surface of the first area 1316_v may contact the first lower insulating layer 131a, and the other surface opposite to the surface may contact the first lower via 133a. A surface of the second area 1316_p may contact the first seed layer 1312, and the other surface opposite to the surface may contact the first lower conductive pattern layer 132a. In this case, the surface of the first area 1316_v may be parallel to the upper surface of the first lower insulating layer 131a. That is, the surface of the first area 1316_v may be parallel to the active surface 110a of the semiconductor chip 110. The surface of the second area 1316_p may not be parallel to the active surface 110a of the semiconductor chip 110, but may be parallel to the surface of the first lower via 133a.

According to an implementation, the first seed layer 1312 and the second seed layer 1316 may form an interface. The first seed layer 1312 and the second seed layer 1316 may include different materials, but one or more implementations are not limited thereto. According to an implementation, the first seed layer 1312 and the second seed layer 1316 may include the same material.

For example, the first seed layer 1312 and the second seed layer 1316 may include at least one material selected from among Ti, Ni, chromium (Cr), W, Ti—Cu, Ti—W, and a combination thereof. However, the materials included in the first seed layer 1312 and the second seed layer 1316 are not limited to the aforementioned ones.

According to an implementation, the first seed layer 1312 may be not only between the first lower conductive pattern layer 132a and the first lower insulating layer 131a but also between the second lower conductive pattern layer 132b and the second lower insulating layer 131b. Also, the second seed layer 1316 may be not only between the first lower via 133a and the first lower insulating layer 131a or between the first seed layer 1312 and the first lower insulating layer 131abut also between the second lower via 133b and the second lower insulating layer 131b or between the first seed layer 1312 and the second lower insulating layer 131b. That is, the first seed layer 1312 and the second seed layer 1316 may both be between conductive vias and conductive patterns of the lower connection structure 130.

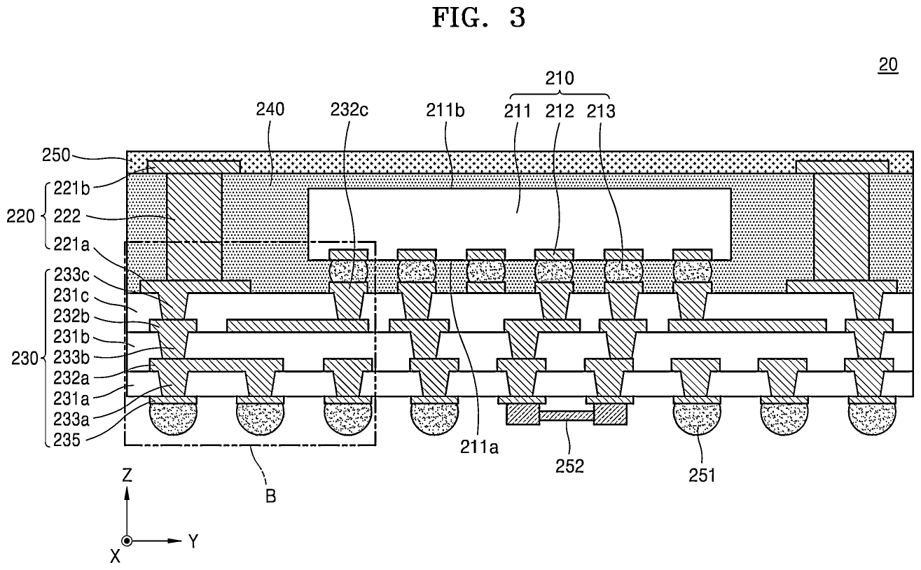

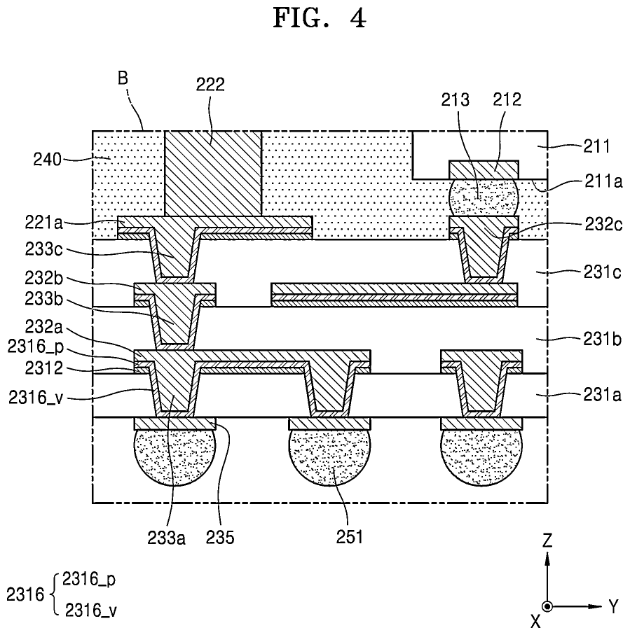

FIG. 3 is a semiconductor package 20 according to another implementation, and FIG. 4 is an enlarged view showing an enlarged region B of FIG. 3. The semiconductor package 20 of FIG. 3 may be manufactured in a chip-last manner, unlike the semiconductor package 10 of FIGS. 1 and 2. Hereinafter, repetitive descriptions of components corresponding to those of FIGS. 1 and 2 are omitted.

Referring to FIGS. 3 and 4, the semiconductor package 20 may include a lower connection structure 230, a semiconductor chip 210 on an upper surface of the lower connection structure 230, an intermediate connection structure 220 on the upper surface of the lower connection structure 230, a molding layer 240 covering an upper surface of the semiconductor chip 210, and an upper connection structure 250 on the molding layer 240. Also, in some implementations, the semiconductor package 20 may further include an external connection terminal 251 arranged on a lower surface of the lower connection structure 230. In some implementations, the semiconductor package 20 may further include a capacitor 252 arranged on the lower surface of the lower connection structure 230.

The lower connection structure 230 may connect between the semiconductor chip 210 and the external connection terminal 251, between the intermediate connection structure 220 and the semiconductor chip 210, and between the intermediate connection structure 220 and the external connection terminal 251. The role of the lower connection structure 230 of FIGS. 3 and 4 may be substantially the same as that of the lower connection structure 130 of FIGS. 1 and 2.

The lower connection structure 230 may include a plurality of lower insulating layers 231a, 231b, and 231c, a plurality of lower conductive pattern layers 232a, 232b, and 232c on the plurality of lower insulating layers 231a, 231b, and 231c, and a plurality of lower via 233a, 233b, and 233c penetrating the lower insulating layers 231a, 231b, and 231c and contacting the plurality of lower conductive pattern layer 232a, 232b, and 232c. Materials and roles of the plurality of lower insulating layers 231a, 231b, and 231c, the plurality of lower conductive pattern layers 232a, 232b, and 232c, and the plurality of lower vias 233a, 233b, and 233c may be substantially and respectively the same as those of the lower insulating layers 121a and 121b, the lower conductive pattern layer 122a, 122b, and 122c, and the lower vias 123a and 123b of FIGS. 1 and 2.

However, unlike the lower vias 133a and 133b shown in FIGS. 1 and 2, the lower vias 233a to 233c shown in FIGS. 3 and 4 may each have a width increasing towards the semiconductor chip 110. That is, the lower vias 233a to 233c shown in FIGS. 3 and 4 may have shapes in which the widths of the lower vias 233a to 233c decrease towards the external connection terminal 251.

According to an implementation, the semiconductor package 20 may further include a lower pad 235 located on the lower surface of the lower insulating layer 231a that is on the lowermost portion of the semiconductor package 20. The lower pad 235 of FIGS. 3 and 4 may have substantially the same role and configuration as those of the lower pad 135 of FIGS. 1 and 2.

The semiconductor chip 210 may include a body 211 and a chip pad 212 on a lower surface of the body 211. However, the semiconductor chip 210 of FIGS. 3 and 4 may further include a chip connection terminal 213, unlike the semiconductor chip 110 of FIGS. 1 and 2. Because the semiconductor chip 210 of FIGS. 3 and 4 is mounted on the lower connection structure 230 after the lower connection structure 230 is completely manufactured, the semiconductor chip 210 may additionally require the chip connection terminal 213.

According to an implementation, the chip connection terminal 213 may contact the third lower conductive pattern layer 232c while attached to the chip pad 212. The third lower conductive pattern layer 232c may be a pattern layer that is arranged on the upper surface of the third lower insulating layer 233c that is the uppermost one among the lower insulating layers 233a to 233c. The semiconductor chip 210 may be electrically connected to the external connection terminal 251 and/or the intermediate connection structure 220 through the chip connection terminal 213 provided between the semiconductor chip 210 and the lower connection structure 230.

A surface of the semiconductor chip 210, on which the integrated circuit is formed, may be referred to as an active surface 211a, while a surface of the semiconductor chip 210, which is opposite to the active surface 211a, may be referred to as an inactive surface 211b. Referring to FIG. 3, the active surface 211a of the semiconductor chip 210 may be the lower surface of the semiconductor chip 210, and the inactive surface 211b of the semiconductor chip 210 may be the upper surface of the semiconductor chip 210.

The molding layer 240 may be arranged on the lower connection structure 230 and cover at least a portion of the semiconductor chip 210. The molding layer 240 may cover side and upper surfaces of the semiconductor chip 210 and the upper surface of the third lower insulating layer 231c. Also, the molding layer 240 may be formed to fill a gap between the semiconductor chip 210 and the upper surface of the third lower insulating layer 231c through a molded underfill process, thus covering the side surface of the chip connection terminal 213.

The intermediate connection structure 220 may be located on the lower connection structure 230 and may be configured to connect the lower connection structure 230 and an upper connection structure (not shown) that may be located on the semiconductor chip 210. The shape of the intermediate connection structure 220 of FIGS. 3 and 4 may be different from that of the intermediate connection structure 120 of FIGS. 1 and 2.

The intermediate connection structure 220 may include a first intermediate pad 221a, a conductive post 222, and a second intermediate pad 221b. In a horizontal perspective, the first intermediate pad 221a may be located on the third lower insulating layer 231c, which is on the uppermost portion of the lower connection structure 230, in the vicinity of the semiconductor chip 210. Also, in a horizontal perspective, the second intermediate pad 221b may be located on the molding layer 240 in the vicinity of the semiconductor chip 210.

The conductive post 222 may be spaced apart from the sidewall of the semiconductor chip 210 in a lateral direction (the X direction and/or the Y direction). The conductive post 222 may have a pillar shape penetrating the molding layer 240 in a vertical direction (e.g., a Z direction). In example implementations, the conductive post 222 and the molding layer 240 may each have an upper surface that is flattened through planarization, and the upper surface of the conductive post 222 may be on the same plane as the upper surface of the molding layer 240. The lower surface of the conductive post 222 may contact the first intermediate pad 221a located on the upper surface of the third lower insulating layer 231c, and the upper surface of the conductive post 222 may contact the second intermediate pad 221b located on the upper surface of the molding layer 240. The conductive post 222 may electrically connect between the lower connection structure 230 and the upper connection structure (not shown). For example, the conductive post 222 may include Cu.

The external connection terminal 251 may be located on the lower surface of the lower pad 235 of the lower connection structure 230. The external connection terminal 251 of FIGS. 3 and 4 may be substantially the same as the external connection terminal 151 of FIGS. 1 and 2.

The lower connection structure 230 may further include a first seed layer 2312 and a second seed layer 2316. The first seed layer 2312 may be between the first lower conductive pattern layer 232a and the first lower insulating layer 231a, and the second seed layer 2316 may include a first area 2316_v between the first lower via 233a and the first lower insulating layer 231a and a second area 2316_p between the first seed layer 2312 and the first lower conductive pattern layer 232a. The first seed layer 2312 and the second seed layer 2316 of FIG. 4 may play substantially the same role and have the same structure as the first seed layer 1312 and the second seed layer 1316 of FIG. 2.

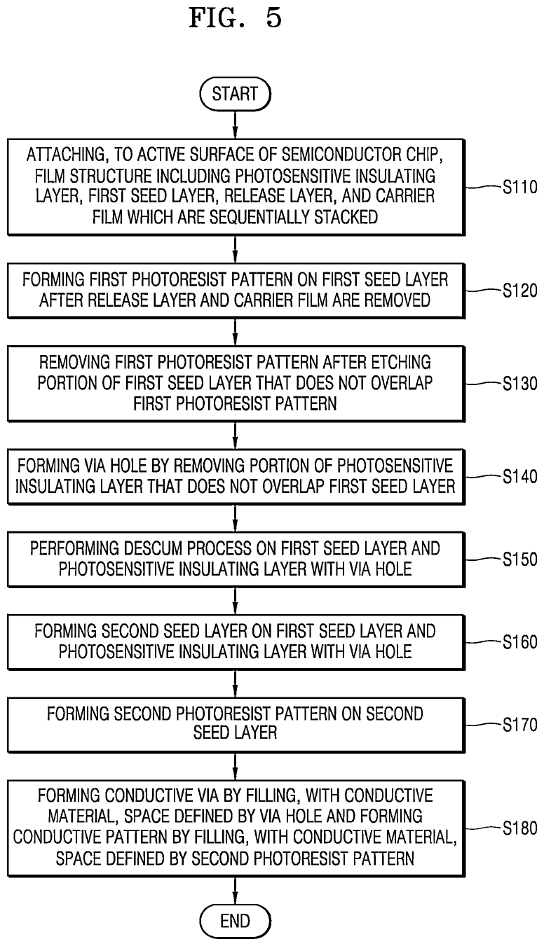

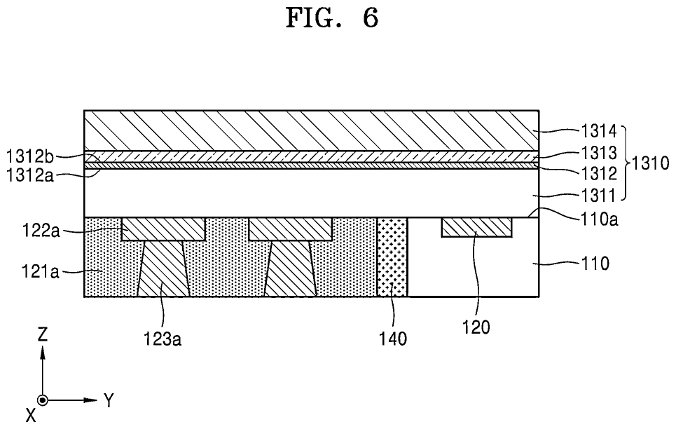

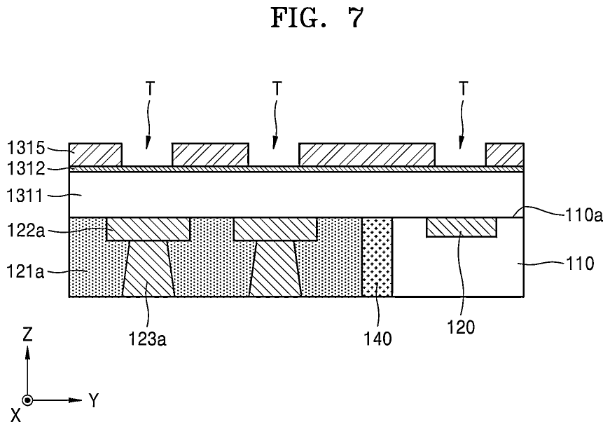

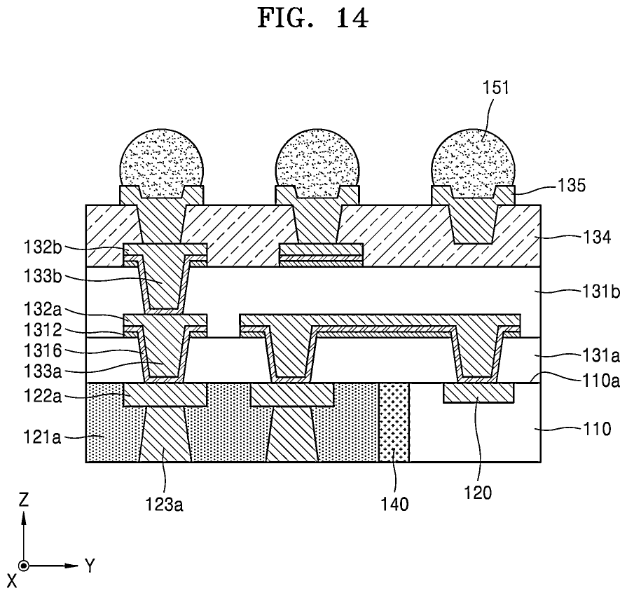

FIG. 5 is a flowchart of a method of manufacturing a semiconductor package, and FIGS. 6 to 14 are cross-sectional views sequentially showing a method of manufacturing a semiconductor package. Hereinafter, the cross-sectional views of FIGS. 6 to 14 are described with reference to FIG. 5.

Referring to FIGS. 5 and 6 together, the method of manufacturing a semiconductor package may include operation S110 of attaching, to the active surface 110a of the semiconductor chip 110, a film structure 1310 including a photosensitive insulating layer 1311, the first seed layer 1312, a release layer 1313, and a carrier film 1314 which are sequentially stacked.

According to an implementation, the semiconductor package regarding the present manufacturing method may be a package manufactured through a chip-first process. Therefore, after the semiconductor chip 110 and the intermediate connection structure (120, see FIG. 1) surrounding the same are formed, the film structure 1310 may be attached to the active surface 110a of the semiconductor chip110 so that the photosensitive insulating layer 1311 may contact the active surface 110a of the semiconductor chip 110.

According to an implementation, the film structure 1310 may include the photosensitive insulating layer 1311, the first seed layer 1312, the release layer 1313, and the carrier film 1314. The photosensitive insulating layer 1311 may be evenly attached to a first surface 1312a of the first seed layer 1312 along the first surface 1312a, while the release layer 1313 may be evenly attached to a second surface 1312b, opposite to the first surface 1312a, along the same. The first seed layer 1312 may be attached to the photosensitive insulating layer 1311 to have a uniform thickness along a surface of the photosensitive insulating layer 1311.

The release layer 1313 may protect a thin layer that is pressure-sensitive. In the present specification, in a process of attaching the carrier film 1314 to the active surface of the semiconductor chip 1310, the release layer 1313 may protect the first seed layer 1312 from external impact.

According to an implementation, the thickness of the release layer 1313 may be in a range from about 0.2 micrometers to about 1 micrometer. When the thickness of the release layer 1313 is greater than 1 micrometer, the cost of manufacturing the release layer 1313 may be excessive. On the other hand, when the thickness of the release layer 1313 is less than about 0.2 micrometers, the release layer 1313 may not properly protect the first seed layer 1312.

For example, the release layer 1313 may include a light to heat conversion (LTHC) coating material.

The carrier film 1314 may be attached to the other surface of the release layer 1313, which is opposite to the surface of the release layer 1313 to which the first seed layer 1312 is attached. The carrier film 1314 may function as a support to make the film structure 1310 stably attached to the active surface 110a of the semiconductor chip 110.

According to an implementation, the thickness of the carrier film 1314 may be in a range from about 10 micrometers to about 50 micrometers. When the thickness of the carrier film 1314 is greater than about 50 micrometers, the cost of manufacturing the carrier film 1314 may be excessively high. On the other hand, when the thickness of the carrier film 1314 is less than about 10 micrometers, the carrier film 1314 may highly likely tear and thus may not properly function as the support.

For example, the carrier film 1314 may include a polyester-based resin film, a polyolefine-based resin film, a polyamide-based resin film, a polyacrylate-based resin film, a thermoplastic polyurethane-based resin film, a polycarbonate-based resin film, an acrylonitrile-butadiene-styrene (ABS) resin film, or the like. Examples of the polyester-based resin film may include a polyethylene terephthalate (PET)-based resin film, examples of the polyamide-based resin film may include a nylon resin film, and examples of the polyolefine-based resin film may include a polyethylene resin film, a polypropylene resin film, and the like.

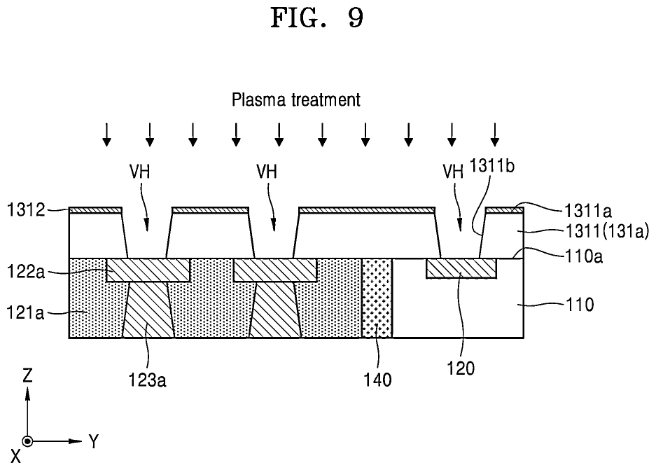

As described below in detail, the first seed layer 1312 may protect the upper surface of the photosensitive insulating layer 1311 from processes including plasma treatment during a descum process performed after a via hole (VH, see FIG. 9) is formed.

According to an implementation, the thickness of the first seed layer 1312 may be in a range from about 0.02 micrometers to about 0.1 micrometers. When the thickness of the first seed layer 1312 is greater than about 0.1 micrometers, the cost of manufacturing the first seed layer 1312 may be excessive. Also, when the thickness of the first seed layer 1312 is greater than about 0.1 micrometers, the integration of the semiconductor package may decrease. On the other hand, when the thickness of the first seed layer 1312 is less than about 0.02 micrometers, there is an increasing risk of damage to the first seed layer 1312 from external impact, and thus, the first seed layer 1312 may not properly protect the photosensitive insulating layer 1311 during the descum process.

For example, the first seed layer 1312 may include at least one of Ti, Ni, Cr, and W. As a specific example, the first seed layer 1312 may include Ti—Cu or Ti—W.

The photosensitive insulating layer 1311 may be an insulating layer formed from the lower insulating layers (131a and 132a, see FIG. 1) as the via hole (VH, see FIG. 9) is formed later. The photosensitive insulating layer 1311 may have a uniform thickness along the first surface 1312a of the first seed layer 1312. Also, the photosensitive insulating layer 1311 may be in a semi-cured state that is the B-stage. That is, during the process of attaching the film structure 1310 to the active surface 110a of the semiconductor chip 110, the photosensitive insulating layer 1311 is not in a gel phase but is already in a film phase, which is itself B-staged. Therefore, when the film structure 1310 is attached to the active surface 110a of the semiconductor chip 110 with heat and pressure, the photosensitive insulating layer 1311 may be completely cured from the B-state to the C-state at a high temperature for a short period of time. When the photosensitive insulating layer 1311 is deposited on the active surface 110a of the semiconductor chip 110 in a liquid state and then cured, the surface of the photosensitive insulating layer 1311 may have irregularities or may not be uniformly formed. When the photosensitive insulating layer 1311 having a multilayered structure is formed, the irregularities or uneven portions may be accumulated, and such an accumulation may hinder the connection of conductive vias or conductive patterns as designed, resulting in the degradation in the reliability of the semiconductor package.

According to an implementation, the thickness of the photosensitive insulating layer 1311 may be in a range from about 2 micrometers to about 15 micrometers. When the thickness of the photosensitive insulating layer 1311 is greater than about 15 micrometers, the cost of manufacturing the photosensitive insulating layer 1311 may be excessively high. Also, when the thickness of the photosensitive insulating layer 1311 is greater than about 15 micrometers, the lower connection structure (130, see FIG. 1) may increase in thickness, and thus, the integration of the semiconductor package may decrease. On the other hand, when the thickness of the photosensitive insulating layer 1311 is less than about 2 micrometers, there is an increasing risk of damage to the photosensitive insulating layer 1311 from external impact, and an insulation effect may degrade, which results in a potential occurrence of leakage current between the lower conductive pattern layers (132a and 132b, see FIG. 1) or the lower vias (133a and 133b, see FIG. 1).

For example, the photosensitive insulating layer 1311 may include silicon oxide with photosensitivity. However, the material included in the photosensitive insulating layer 1311 is not limited to the material stated above.

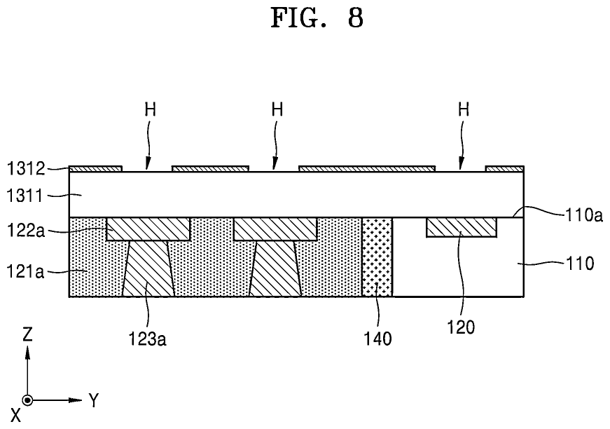

Referring to FIGS. 5 and 7 together, the method of manufacturing a semiconductor package may include operation S120 of forming a first photoresist pattern 1315 on the first seed layer 1312 after the release layer 1313 and the carrier film 1314 are removed.

After a lower surface of the photosensitive insulating layer 1311 is attached to the active surface 110a of the semiconductor chip 110, the release layer 1313 and the carrier film 1314 may be removed. Then, the first photoresist pattern 1315 may be formed on the first seed layer 1312. The first photoresist pattern 1315 may have a plurality of trenches T. The trenches T may each be a region that defines a pattern of a hole H to be formed in the first seed layer 1312. The trenches T may be formed in the first photoresist pattern 1315 through photolithography. In this case, a portion of the first seed layer 1312 may be exposed through the trenches T. In an implementation, the trench T may not be formed in a tapered shape but rather be formed in a cylindrical shape with a uniform width in a vertical direction (the Z direction).

Referring to FIGS. 5, 7, and 8 together, the method of manufacturing a semiconductor package may include operation S130 of removing the first photoresist pattern 1315 after etching a portion of the first seed layer 1312 that does not overlap the first photoresist pattern 1315.

According to an implementation, the first photoresist pattern 1315 may protect the first seed layer 1312 while a portion of the first seed layer 1312 is etched. The process of etching a portion of the first seed layer 1312 may be an etching process having etch selectivity. A plurality of holes H may be formed in the first seed layer 1312 by etching a portion of the first seed layer 1312. In this case, the holes H may be regions that overlap the trenches T of the first photoresist pattern 1315 in the vertical direction (the Z direction).

Referring to FIGS. 5 and 9 together, the method of manufacturing a semiconductor package may include operation S140 of forming a via hole VH by removing a portion of the photosensitive insulating layer 1311 that does not overlap the first seed layer 1312 and operation S150 of performing a descum process on the first seed layer 1312 and the photosensitive insulating layer 1311 with the via hole VH.

According to an implementation, the via hole VH may be formed by etching the photosensitive insulating layer 1311. In this case, the via hole VH may extend from the hole H in the first seed layer 1312. The first seed layer 1312 may protect a portion of the photosensitive insulating layer 1311, that is, a region that is not intended to become the via hole VH, during the process of forming the via hole VH in the photosensitive insulating layer 1311. When the via hole VH is formed, a conductive pattern (e.g., the first intermediate conductive pattern layer 122a) may be exposed through the via hole VH. The via hole VH may have a tapered configuration in which the width of the via hole VH decreases towards the active surface 110a of the semiconductor chip 110. When the via hole VH is formed in the photosensitive insulating layer 1311, the photosensitive insulating layer 1311 may be defined as the first lower insulating layer 131a forming the lower connection structure (130, see FIG. 1).

Then, the descum process may be performed on the first seed layer 1312 and the photosensitive insulating layer 1311 including the via hole VH. The descum process may be a process of removing residue or scum remaining in the via hole VH after the via hole VH is formed in the photosensitive insulating layer 1311. In an implementation, the descum process may proceed through a plasma treatment process. For example, during the plasma treatment process, a treatment precursor, a recovery precursor, or a mixture of carrier gases may be used.

In an implementation, the treatment precursor may react with the residue or scum and may be used to remove the same. For example, the treatment precursor may be an oxidation precursor such as oxygen (O₂). However, one or more implementations are not limited thereto, and the treatment precursor may include ozone (O₃), nitrogen (N₃), or ammonia (NH₃).

However, the treatment precursor may react with the photosensitive insulating layer 1311 and damage a bonding relationship (e.g., silicon-oxygen bonds, etc.) of materials included in the photosensitive insulating layer 1311. Therefore, the recovery precursor may be used to prevent the damage caused by the treatment precursor. The recovery precursor may be used to recover molecular bonds of the treatment precursor damaged by the treatment precursor. For example, the recovery precursor may include methane, carbon dioxide, ethane, propane, or a combination thereof.

The carrier gas may be used to control and dilute the treatment precursor and the recovery precursor and help ignition of the treatment precursor and the recovery precursor by lowering the voltage required for the ignition of the treatment precursor and the recovery precursor. The carrier gas may include an inert gas, such as argon, helium, or krypton.

According to an implementation, when the descum process is performed, a surface parallel to the active surface 110a of the photosensitive insulating layer 1311 may be defined as a flat surface 1311a, and a surface not parallel to the active surface 110a may be defined as an inclined surface 1311b. In this case, the flat surface 1311a of the photosensitive insulating layer 1311 may contact the first seed layer 1312, and the inclined surface 1311b may be exposed through the via hole VH. During the descum process, the inclined surface 1311b is exposed through the via hole VH, and thus, residue or scum in the inclined surface 1311b may be removed. However, because the flat surface 1311a is not exposed by the first seed layer 1312, the flat surface 1311a may not undergo the plasma treatment. When plasma treatment is performed during the descum process, the surface roughness of the photosensitive insulating layer 1311 may decrease. When the surface roughness of the flat surface 1311a of the photosensitive insulating layer 1311 is reduced, the surface adhesion decreases when other seed layers and the like are deposited in a subsequent process, and thus, the flat surface 1311a of the photosensitive insulating layer 1311 may not properly adhere to the first seed layer 1312. In the present implementation, however, the flat surface 1311a of the photosensitive insulating layer 1311 already adheres to the first seed layer 1312 before the descum process, and because the flat surface 1311a is not exposed during the plasma treatment, the adhesion between the first seed layer 1312 and the photosensitive insulating layer 1311 may be appropriately maintained even after the descum process.

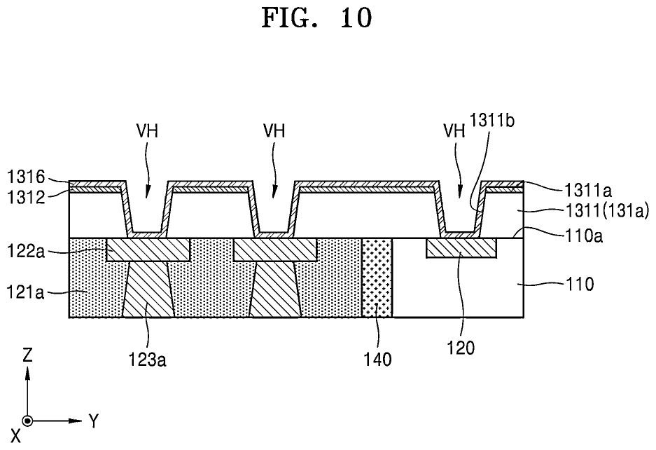

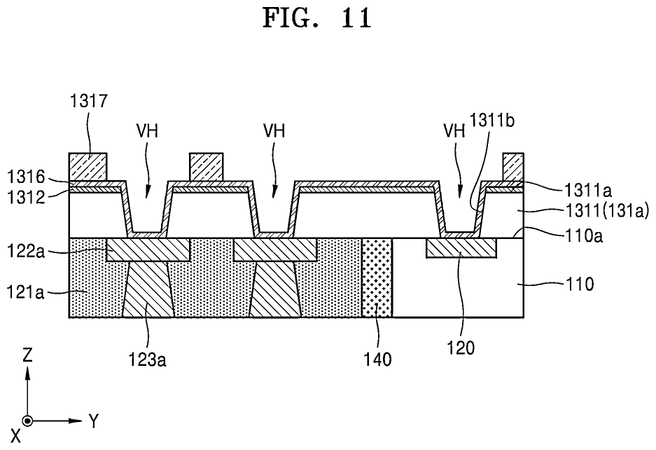

Referring to FIGS. 5 and 10 together, the method of manufacturing a semiconductor package may include operation S160 of forming the second seed layer 1316 on the first seed layer 1312 and the photosensitive insulating layer 1311 in which the via hole VH is formed.

The second seed layer 1316 may be formed through physical vapor deposition (PVD), chemical vapor deposition (CVD), atomic layer deposition (ALD), or a combination thereof. The thickness of the second seed layer 1316 may be substantially the same as that of the first seed layer 1312, but one or more implementations are not limited thereto. The thickness of the second seed layer 1316 may be different from that of the first seed layer 1312.

According to an implementation, the second seed layer 1316 may be formed along the upper surface and the side surface of the first seed layer 1312 and along the via hole VH of the photosensitive insulating layer 1311. The second seed layer 1316 may have a thickness that is uniform in the lengthwise direction of the second seed layer 131. The flat surface 1311a of the photosensitive insulating layer 1311 contacts the first seed layer 1312, and the inclined surface 1311b of the photosensitive insulating layer 1311 contacts the second seed layer 1316. A region of the second seed layer 1316 with an upper surface parallel to the active surface 110a may contact the first seed layer 1312.

According to an implementation, the second seed layer 1316 and the first seed layer 1312 may form an interface. For example, the second seed layer 1316 may include at least one of Ti, Ni, Cr, and W. As a specific example, the second seed layer 1316 may include Ti—Cu or Ti—W.

In this case, the second seed layer 1316 and the first seed layer 1312 may include different materials, but one or more implementations are not limited thereto., the second seed layer 1316 and the first seed layer 1312 may include the same material.

Referring to FIGS. 5 and 11 together, the method of manufacturing a semiconductor package may include operation S170 of forming a second photoresist pattern 1317 on the second seed layer 1316.

In this case, the second photoresist pattern 1317 may be formed not to overlap the via hole VH in the vertical direction (the Z direction). The second photoresist pattern 1317 may define a region in which the first lower via 133a and the first lower conductive pattern layer 132a are to be formed through a plating process. For example, the material included in the second photoresist pattern 1317 may be substantially the same as the material included in the first photoresist pattern 1315.

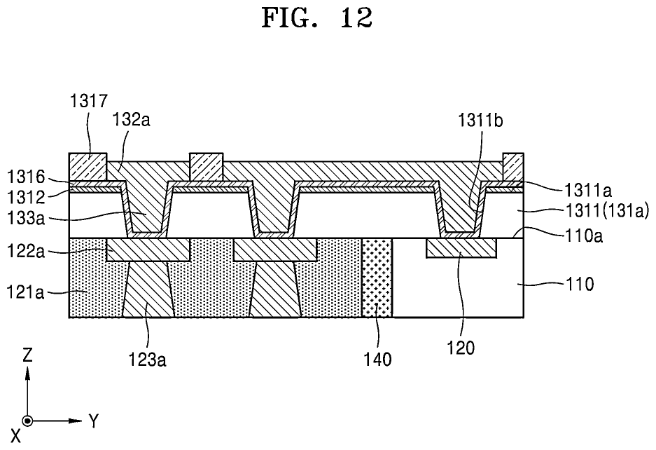

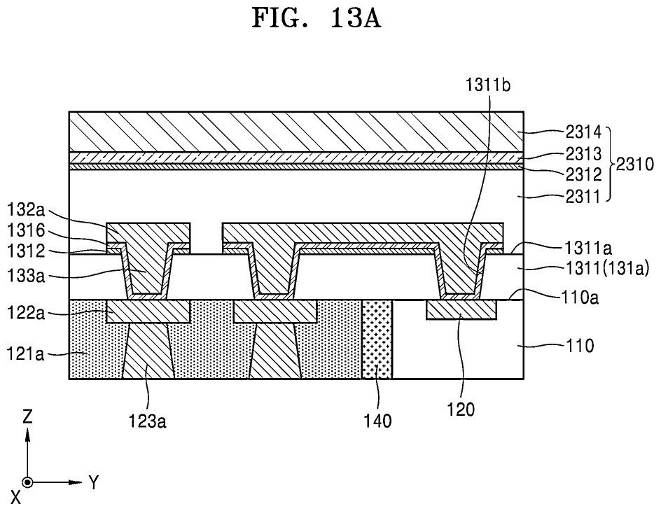

Referring to FIGS. 5 and 12 together, the method of manufacturing a semiconductor package may include operation S180 of forming a conductive via by filling, with a conductive material, a space defined by the via hole VH and forming a conductive pattern by filling, with the conductive material, a space defined by the second photoresist pattern 1317.

In this case, the conductive via may be the first lower via 133a, and the conductive pattern may be the first lower conductive pattern layer 132a. The process of forming the conductive via and the conductive pattern by filling the conductive material therein may be a plating process. The space defined by the second photoresist pattern 1317 may be a region on the upper surface of the second seed layer 1316 that is between portions of the second photoresist pattern 1317.

Then, referring to FIGS. 12, 13A, and 14, the first seed layer 1312 and the second seed layer 1316 that overlap the second photoresist pattern 1317 may be removed. Then, the second photoresist pattern 1317 may be removed together. After the second photoresist pattern 1317 is removed together with the first seed layer 1312 and the second seed layer 1316 which overlap the second photoresist pattern 1317, a second film structure 2310 that includes the second photosensitive insulating layer 2133 covering the upper and side surfaces of the first lower conductive pattern layer 132a may be attached. Then, the lower connection structure (130, see FIG. 1) may be formed by repeatedly performing the processes shown in FIGS. 6 to 12.

In this case, the flat surface 1311a of the first lower insulating layer 131a may contact the first seed layer 1312, and the inclined surface 1311b of the first lower insulating layer 131a may contact the second seed layer 1316. Also, the first lower via 133a may have a tapered shape in which the width of the first lower via 133a decreases towards the active surface 110a.

According to an implementation, as the second photoresist pattern 1317 is removed together with the first seed layer 1312 and the second seed layer 1316 which overlap the second photoresist pattern 1317, the side surface of the first seed layer 1312, the side surface of the second seed layer 1316, and the side surface of the first lower conductive pattern layer 132a may be on the same plane.

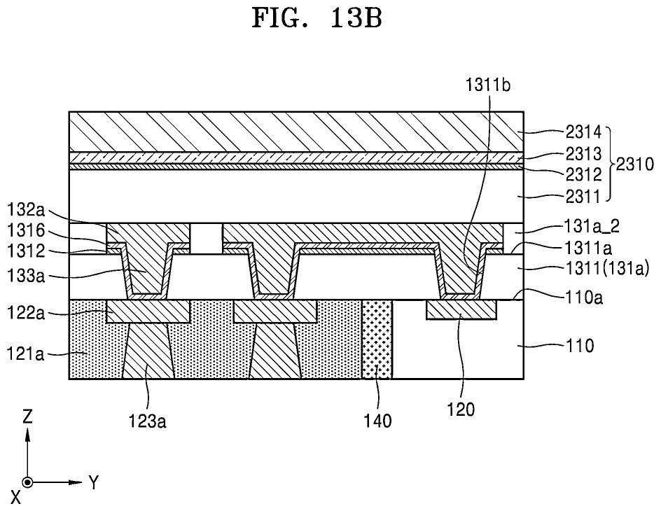

The second film structure 2310 of FIG. 13B may be substantially the same as the film structure 1310 of FIG. 6 and includes a photosensitive insulating layer 2311, a first seed layer 2312, a release layer 2313, and a carrier film 2314 which are sequentially stacked.

FIG. 13B shows another implementation of the process of FIG. 13A. Referring to FIG. 13B, after the second photoresist pattern 1317 is removed together with the first seed layer 1312 and the second seed layer 1316 which overlap the second photoresist pattern 1317, an auxiliary insulating layer 131a_2 may be formed, the auxiliary insulating layer covering the side surface of the first lower conductive pattern layer 132a, the side surface of the first seed layer 1312, and the side surface of the second seed layer 1316. An upper surface of the auxiliary insulating layer 131a_2 may be located on the same plane as the upper surface of the first lower conductive pattern layer 132a.

When the auxiliary insulating layer 131a_2 is formed, and then when the second photosensitive insulating layer 2311 of the second film structure 2310 is attached to the upper surface of the first lower conductive pattern layer 132a, a planar lower surface of the second photosensitive insulating layer 2311 may be uniformly attached to the upper surface of the first lower conductive pattern layer 132a and the upper surface of the auxiliary insulating layer 131a_2 without any step difference. The material included in the auxiliary insulating layer 131a_2 may be, for example, substantially the same as that included in the second photosensitive insulating layer 2311 or the first photosensitive insulating layer 1311.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While the inventive concept has been particularly shown and described with reference to implementations thereof, it will be understood that various changes in form and details may be made therein without departing from the spirit and scope of the following claims.

What is claimed is:

1. A method of manufacturing a semiconductor package that comprises a semiconductor chip comprising an active surface and an inactive surface opposite to the active surface, the method comprising:
attaching, to the active surface of the semiconductor chip, a film structure comprising an insulating layer and a first seed layer contacting the insulating layer;
forming a via hole penetrating the insulating layer and the first seed layer;
performing a descum process on the insulating layer and the first seed layer in which the via hole is formed;
forming a second seed layer on the insulating layer and the first seed layer on which the descum process was performed;
forming a photoresist pattern on the second seed layer; and
forming a conductive via by filling a space defined by the via hole with a conductive material and forming a conductive pattern by filling a space defined by the photoresist pattern with the conductive material.

2. The method of claim 1, wherein, in performing the descum process, a surface of the insulating layer, which is parallel to the active surface of the semiconductor chip, contacts the first seed layer, and a surface of the insulating layer, which is not parallel to the active surface of the semiconductor chip, is exposed to a plasma.

3. The method of claim 1, wherein, in forming the conductive via and forming the conductive pattern, a surface of the insulating layer, which is parallel to the active surface, contacts the first seed layer, and a surface of the insulating layer, which is not parallel to the active surface of the semiconductor chip, contacts the second seed layer.

4. The method of claim 1, wherein, in forming the second seed layer, a surface of the insulating layer, which is not parallel to the active surface, contacts the second seed layer.

5. The method of claim 1, wherein, in forming the second seed layer, the first seed layer and the second seed layer form an interface.

6. The method of claim 1, wherein, in forming the conductive via and forming the conductive pattern, a width of the conductive via decreases towards the active surface of the semiconductor chip.

7. The method of claim 1, wherein, in forming the conductive via and forming the conductive pattern, a side surface of the first seed layer, a side surface of the second seed layer, and a side surface of the conductive pattern are located on a same plane.

8. The method of claim 1, wherein, performing the descum process comprises applying a plasma treatment.

9. The method of claim 1, wherein the first seed layer includes a same material as the second seed layer.

10. The method of claim 1, wherein the first seed layer includes tungsten (W), and the second seed layer includes titanium (Ti) or copper (Cu).

11. The method of claim 1, wherein a thickness of the first seed layer is in a range from about 0.02 micrometers to about 0.1 micrometers.

12. A method of manufacturing a semiconductor package that comprises a semiconductor chip comprising an active surface and an inactive surface opposite to the active surface, the method comprising:
attaching, to the active surface, a film structure comprising an insulating layer, a first seed layer, a release layer, and a carrier film which are sequentially stacked;
forming a first photoresist pattern on the first seed layer after the release layer and the carrier film are removed;
removing the first photoresist pattern after etching a portion of the first seed layer that does not overlap the first photoresist pattern;
forming a via hole by removing a portion of the insulating layer that does not overlap the first seed layer;
performing a descum process on the first seed layer and the insulating layer in which the via hole is formed;
forming a second seed layer on the first seed layer and the insulating layer on which the descum process was performed;
forming a second photoresist pattern on the second seed layer; and
forming a conductive via by filling a space defined by the via hole with a conductive material and forming a conductive pattern by filling a space defined by the second photoresist pattern with the conductive material.

13. The method of claim 12, wherein, in attaching the film structure to the active surface of the semiconductor chip, the insulating layer is in a semi-cured state that is a B stage.

14. The method of claim 12, wherein, in forming the conductive via and forming the conductive pattern, a surface of the insulating layer, which is parallel to the active surface, contacts the first seed layer, and a surface of the insulating layer, which is not parallel to the active surface, contacts the second seed layer.

15. The method of claim 12, wherein, in forming the conductive via and forming the conductive pattern, a side surface of the first seed layer, a side surface of the second seed layer, and a side surface of the conductive pattern are located on a same plane.

16. The method of claim 12, wherein a thickness of the carrier film is in a range from about 10 micrometers to about 50 micrometers.

17. The method of claim 12, wherein a thickness of the release layer is in a range from about 0.2 micrometers to about 1 micrometer.

18. A method of manufacturing a semiconductor package that comprises a semiconductor chip comprising an active surface and an inactive surface opposite to the active surface and an intermediate connection structure having a multilayered structure and surrounding the semiconductor chip, the method comprising:
attaching, to the active surface, a film structure comprising a photosensitive insulating layer, a first seed layer, a release layer, and a carrier film which are sequentially stacked;
forming a first photoresist pattern on the first seed layer after the release layer and the carrier film are removed;
removing the first photoresist pattern after etching a portion of the first seed layer that does not overlap the first photoresist pattern;
forming a via hole by removing a portion of the photosensitive insulating layer that does not overlap the first seed layer;
performing a descum process on the first seed layer and the photosensitive insulating layer in which the via hole is formed;
forming a second seed layer on the first seed layer and the photosensitive insulating layer on which the descum process was performed;
forming a second photoresist pattern on the second seed layer; and
forming a conductive via by filling a space defined by the via hole with a conductive material and forming a conductive pattern by filling a space defined by the second photoresist pattern with the conductive material.

19. The method of claim 18, wherein the conductive via and the conductive pattern are electrically connected to the intermediate connection structure.

20. The method of claim 18, wherein the intermediate connection structure comprises:
a plurality of intermediate conductive pattern layers with different vertical levels; and
a plurality of intermediate vias respectively arranged between the plurality of intermediate conductive pattern layers.
